(19) United States
(12) Patent Application Publication
(10) Pub. No.: US 2014/0014173 A1
(43) Pub. Date: Jan. 16, 2014

(54) Solar Cell and Method for Manufacturing the Same

(71) Applicants: Deoc Hwan Hyun, Daejeon (KR); Jae Eock Cho, Daejeon (KR); Dong Ho Lee, Daejeon (KR); Hyun Cheol Ryu, Daejeon (KR); Yong Hwa Lee, Seoul (KR); Gang Il Kim, Seoul (KR); Gui Ryong Ahn, Daejeon (KR)

(72) Inventors: Deoc Hwan Hyun, Daejeon (KR); Jae Eock Cho, Daejeon (KR); Dong Ho Lee, Daejeon (KR); Hyun Cheol Ryu, Daejeon (KR); Yong Hwa Lee, Seoul (KR); Gang Il Kim, Seoul (KR); Gui Ryong Ahn, Daejeon (KR)

(73) Assignee: HANWHA CHEMICAL CORPORATION, Seoul (KR)

(21) Appl. No.: 14/006,755

(22) PCT Filed: Feb. 23, 2012
(86) PCT No.: PCT/KR2012/001371

§ 371 Date: Sep. 23, 2013

(30) Foreign Application Priority Data
Mar. 30, 2011 (KR) 10-2011-0028781

(51) Int. Cl. H01L 31/0236

(52) U.S. Cl. CPC H01L 31/02363
USPC 136/256; 438/71

(57) ABSTRACT

Provided are a solar cell and a method for manufacturing the same, and more particularly, a solar cell for forming a selective emitter structure and a surface texture using dry plasma etching at the same time, and a method for manufacturing the same. The solar cell includes a silicon semiconductor substrate; an emitter doping layer having a surface, which is textured by a texturing process on an upper portion of the silicon semiconductor substrate and selectively doped; an anti-reflective film layer formed on a front of the substrate; a front electrode accessing to the emitter doping layer by penetrating the anti-reflective film layer; and a rear electrode accessing to a rear of the silicon semiconductor substrate.

### TECHNICAL FIELD

The present invention relates to a solar cell and a method for manufacturing the same, and more particularly, to a solar cell for forming a selective emitter structure and a surface texture using dry plasma etching at the same time, and a method for manufacturing the same.

### BACKGROUND ART

Recently, as the existing energy resources, such as oil, coal and the like, became exhausted, alternative energy sources thereto have attracted attention. Among these alternative energy sources, solar cells are receiving particular attention because they are resourceful and do not cause environmental problems.

Solar cells include solar heat cells that generate steam necessary to rotate a turbine using solar heat and solar light cells that convert solar energy into electric energy using semiconductor properties. Solar cells are generally called solar light cells (hereinafter, referred to as ‘solar cells’).

Solar cells are largely classified into silicon solar cells, compound-semiconductor solar cells and tandem solar cells according to raw materials. Among these three kinds of solar cells, silicon solar cells are generally used in the solar cell market.

When solar light enters such a solar cell, electrons and holes are generated from a silicon semiconductor doped with impurities by a photovoltaic effect.

Such electrons and holes are respectively drawn toward an N-type semiconductor and a P-type semiconductor to move to an electrode connected with a lower portion of a substrate and an electrode connected with an upper portion of an emitter doping layer. When these electrodes are connected with each other by electric wires, electric current flows.

Recently, in order to reduce contact resistance between the electrode and the emitter doping layer, a doping region contacting the electrode among the emitter doping layers is formed with heavy doping and other regions are formed with light doping. Accordingly, a life time of a carrier is increased. Such a structure is called a selective emitter.

A process of forming the selective emitter doping layer by etch-back has a benefit that efficiency is improved. However, since the process requires an expensive dry plasma etching device, it is difficult to apply the process to a mass production line.

Also, the selective emitter greatly improves efficiency by reducing contact between the electrode and the emitter doping layer. However, there is a disadvantage that the manufacturing process is complicated and a manufacturing cost is very high.

A wet etching process is generally used in surface texturing. However, when a dry etching process is used, there is an advantage that a surface reflection rate decreases but there is also a disadvantage that a unit cost for the process increases.

### DISCLOSURE OF INVENTION

### Technical Problem

The present invention is invented to solve the problems of the prior art described above, and an embodiment of the is to provide a solar cell that decreases the number of processes and a unit cost by simultaneously performing surface texturing by dry plasma etching and selective doping for improving efficiency of the silicon solar cell, and a method for manufacturing the same.

### Solution to Problem

To achieve the embodiment of the present invention, provided is a solar cell that is integrally manufactured by performing surface texturing and selective doping by a Reactive Ion Etching (RIE) process. The solar cell, includes: a silicon semiconductor substrate; an emitter doping layer having a surface, which is textured by a texturing process on an upper portion of the silicon semiconductor substrate and selectively doped; an anti-reflective film layer formed on a front of the substrate; a front electrode accessing to the emitter doping layer by penetrating the anti-reflective film layer; and a rear electrode accessing to a rear of the silicon semiconductor substrate.

According to another exemplary embodiment, provided is a solar cell manufacturing method, includes the steps of: preparing a silicon wafer; forming a silicon semiconductor substrate by Sawing Damage Removal (SDR) after sawing the silicon wafer; forming an emitter doping layer on an upper portion of the silicon semiconductor substrate; forming an etching mask pattern at a front electrode junction point on the emitter doping layer by a screen print; performing Reactive Ion Etching (RIE) texturing on a surface of the emitter doping layer using the etching mask pattern as a mask and forming selective doping to form an emitter etch-back at the same time; removing an etching mask pattern remaining after the etch-back; removing damages on the surface of the emitter doping layer using Damage Removal Etching (DRE) on the silicon semiconductor substrate; forming an anti-reflective film on a front of the silicon semiconductor substrate; forming a front electrode by penetrating the anti-reflective film; and forming a rear electrode on a rear of the silicon semiconductor substrate.

The silicon semiconductor substrate is doped with impurities of a Group 3 element or a Group 5 element, and the emitter doping layer is classified into a first emitter doping layer doped with impurities of the Group 3 element or the Group 5 element at a high concentration and a second emitter doping layer doped with the impurities of the Group 3 element or the Group 5 element at a low concentration, wherein the first emitter doping layer is a region accessing to the front electrode.

The first emitter doping layer is a region accessing to the front electrode.

In the step of forming the etching mask pattern, the etching mask pattern is formed by screen-printing a paste.

In the step of forming the selective doping, etch-back on the emitter doping layer is performed using dry etchant, in which etch gas and O2 are mixed, and surface texturing is performed at the same time.

In the emitter doping layers, the first emitter doping layer has a sheet resistance (Emitter Rsh) of 60 ohm/sq or less.

In the emitter doping layers, the second emitter doping layer has an emitter Rsh ranging from 70 ohm/sq to 120 ohm/sq.

The emitter doping layer after etch-back via the step of forming the selective doping has the greater emitter Rsh than the emitter doping layer before etch-back.

A line width of the first emitter doping layer ranges from 50 to 200 μm.

### Advantageous Effects of Invention

According to the present invention, since selective doping and surface texture are simultaneously performed in a single dry plasma etching device, it is possible to realize a highly efficient solar cell.

Also, as another effect of the present invention, it is possible to manufacture an etch-back selective doping solar cell that is applicable to a mass production line by decreasing a unit cost by removing a wet texturing device.

### BRIEF DESCRIPTION OF DRAWINGS

The above and other objects, features and advantages of the present invention will become apparent from the following description of preferred embodiments given in conjunction with the accompanying drawings, in which:

FIG. 1 is a flow diagram describing a process for manufacturing a solar cell by simultaneously performing surface texturing and selective doping of a silicon solar cell using dry plasma etching according to an exemplary embodiment.

FIGS. 2 to FIG. 9 are cross-sectional views showing the process for manufacturing the solar cell according to the flow diagram shown in FIG. 1.

### DETAILED DESCRIPTION OF MAIN ELEMENTS

200: silicon semiconductor substrate

210: emitter doping layer

220: etching mask pattern

230: second emitter doping layer

240: first emitter doping layer

231: convex 233: concave

250: anti-reflective film layer

270: front electrode

280: rear electrode

290: P+ forming layer

### BEST MODE FOR CARRYING OUT THE INVENTION

The present invention may be diversely modified and have a plurality of exemplary embodiments. Accordingly, specific exemplary embodiments will be exemplified on accompanying drawings and described in detail. However, it will be apparent that the present invention is not limited to the above exemplary embodiments. It will be understood that modifications, equivalents and substitutions for components of the specifically described embodiments of the present invention may be made by those skilled in the art without departing from the spirit and scope of the present invention. Similar reference numerals are used in similar constituent elements in describing each drawing.

The terms “first” and “second” may be used in describing diverse constituent elements but should not limit the constituent elements. The terms are used with the object of distinguishing one constituent element from another constituent element. For example, a first constituent element may be called a second constituent element and similarly, a second constituent element may be called a first constituent element. The term “and/or” includes combinations of a plurality of related items described herein or any one of the plurality of related items described herein.

When it is mentioned that any constituent element “is connected to” or “is in contact with” another constituent element, the former may be directly connected to or in contact with the latter. Otherwise, it will be understood that any other constituent elements may exist between the former and the latter. On the other hand, when it is mentioned that any constituent element “is directly connected to” or “is directly in contact with” another constituent element, it will be understood that there is no constituent element between the former and the latter.

The terms used in this specification is provided to describe the specific exemplary embodiments but they are not provided to limit the scope of the present invention. A singular number includes a plural number unless a concise and apparent meaning is given to the expression. In this application, it will be understood that the terms “include” or “have” indicate that features, numerals, processes, operations, constituent elements, components or combinations thereof described in the specification exist but does not exclude existing of other features, numerals, processes, operations, constituent elements, components or combinations thereof or additional possibilities.

Unless otherwise defined, all terms including technical or scientific terms used herein have the same meaning as those generally understood by those skilled in the art of the present invention. It will be also understood that such terms that are generally used and defined in the dictionary have contextually identical meaning with the words of related technologies. Unless clearly defined in this application, they will not be understood as ideological or overly formal meanings.

According to the present invention, a solar cell and a method for manufacturing the same will be described in detail with reference to accompanying drawings.

Generally, a silicon solar cell includes a substrate made of a p-type silicon semiconductor and an emitter doping layer, wherein a p-n junction is formed at the interface between the substrate and the emitter doping layer, similarly to a diode.

When solar light enters a solar cell having such a structure, electrons and holes are generated from a silicon semiconductor doped with impurities by a photovoltaic effect.

For reference, electrons are generated from an emitter doping layer made of an n-type silicon semiconductor as many carriers, and holes are generated from a substrate made of a p-type silicon semiconductor as many carriers.

The electrons and holes generated by a photovoltaic effect are respectively drawn toward an n-type semiconductor and a p-type semiconductor to move to an electrode connected with the lower portion of the substrate and an electrode connected with the upper portion of the emitter doping layer. When these electrodes are connected with each other by electric wires, electric current flows.

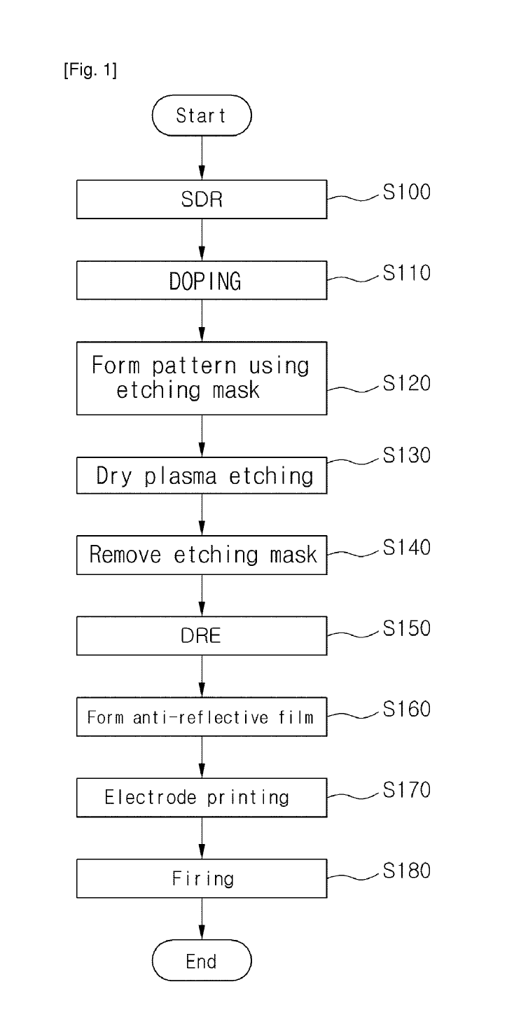

FIG. 1 is a flow diagram describing a process for manufacturing the solar cell by simultaneously performing surface texturing and selective doping of the silicon solar cell using dry plasma etching according to an exemplary embodiment.

That is, FIG. 1 shows a step of manufacturing the solar cell by performing surface texturing and selective doping integrally according to a Reactive Ion Etching (RIE) process. With reference to FIG. 1, the solar cell is manufactured via processes as below.

(a) A silicon wafer substrate doped with impurities of a Group 3 element is prepared, and sawing on the prepared silicon wafer substrate to form a silicon semiconductor substrate and Sawing Damage Removal (SDR) on a silicon semiconductor substrate are performed at step S100.

That is, the SDR process required to remove damage due to sawing is performed by Saw Damage Etching (SDE). In the SDE process, the substrate surface is etched using a chemical or an oxide film, i.e., a phosphoric silicate glass layer, formed on the surface is removed.

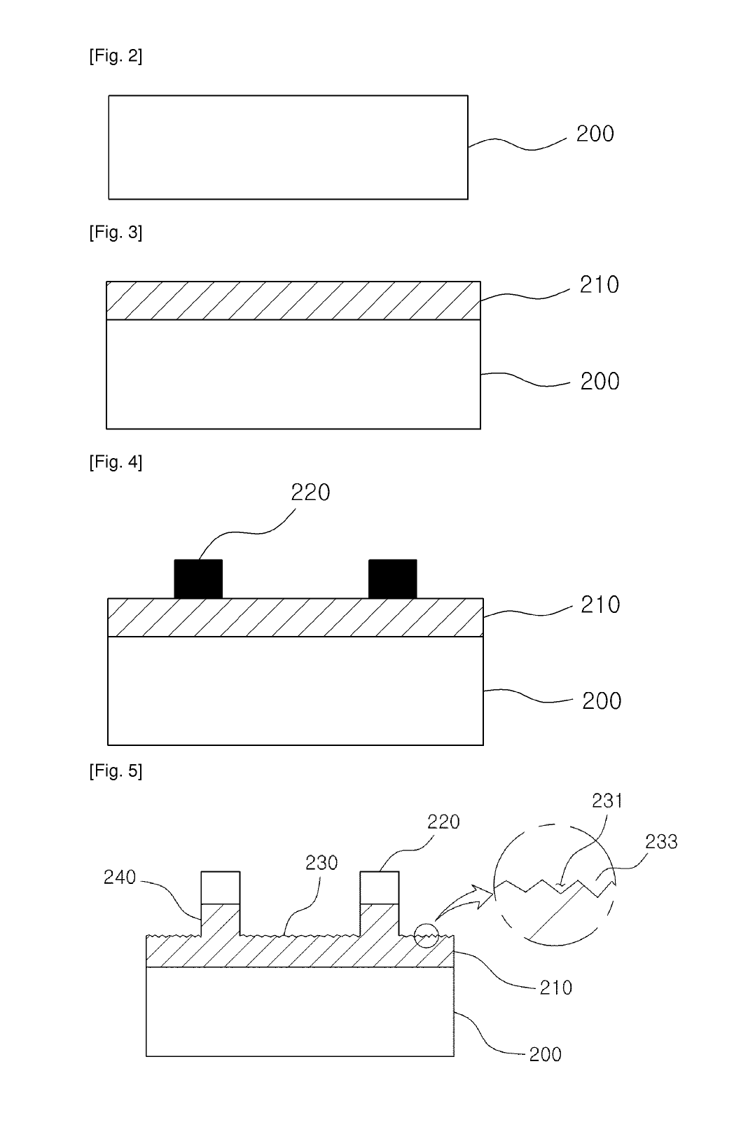

FIG. 2 shows a created silicon semiconductor substrate 200.

(b) An emitter doping layer is formed on an upper portion of the substrate by doping impurities having a Group 5 element on an upper portion of the silicon semiconductor substrate 200 (see FIG. 2) at step S110 (see FIG. 3). Accordingly, an emitter doping layer 210 of a predetermined thickness is formed on the silicon semiconductor substrate 200.

Such a doping process includes

a Chemical Vapor Deposition (CVD) process, an ion plating process, a plasma Chemical Vapor Deposition (CVD) process using Direct Current (DC), Radio Frequency (RF) or thermal, a Physical Vapor Deposition (PVD) process, an Electron Cyclotron Resonance (ECR) process, an epitaxial growth process, a sputtering process using DC, RF or ion beam, and a laser synthesis process.

(c) An etching mask pattern is formed on a front electrode junction point on the emitter doping layer, i.e., a position for forming a front electrode, using a screen print at step S120 (see FIG. 4). Therefore, the emitter doping layer 210 on the silicon semiconductor substrate 200, and an etching mask pattern 220 on the emitter doping layer 210 are laminated in order.

The etching mask pattern is formed by screen printing a glass frit paste including inorganic particles, an organic solvent and a resin.

(d) A selective doping is performed by RIE texturing a surface of the emitter doping layer 210 using the etching mask pattern 220 as a mask (see FIG. 4) and forming an emitter etch-back at the same time at step S130 (see FIG. 5). Accordingly, the emitter doping layer 210 laminated on the silicon semiconductor substrate 200 is divided into a first emitter doping layer 240 and a second emitter doping layer 230.

That is, the first emitter doping layer 240 doped with impurities of the Group 5 element at high concentration and the second emitter doping layer 230 doped with impurities of the Group 5 element at low concentration are formed in steps and divided. Among the emitter doping layers, doping regions contacting the electrode are formed with heavy doping and other regions are formed with light doping in increase a life time of a carrier. This structure is called a selective emitter.

The step S130 of FIG. 1 will be described hereinafter. Since the texturing process is performed together at the step S13, concave surfaces 231 and 233 are formed on the second emitter doping layer 230 as shown in the extended figure of FIG. 5. Therefore, a light receiving efficiency is improved by the concave surfaces. A sheet resistance (Emitter Rsh) of the second emitter doping layer 230 is within the range of 70 Ohm/sq to 120 Ohm/sq and the emitter Rsh of the first emitter doping layer 240 is within the range of 60 ohm/sq or less.

Alternatively, it is also possible to perform etch-back and surface texturing on the emitter doping layer using dry etchant such as Etch Gas+O2 plasma.

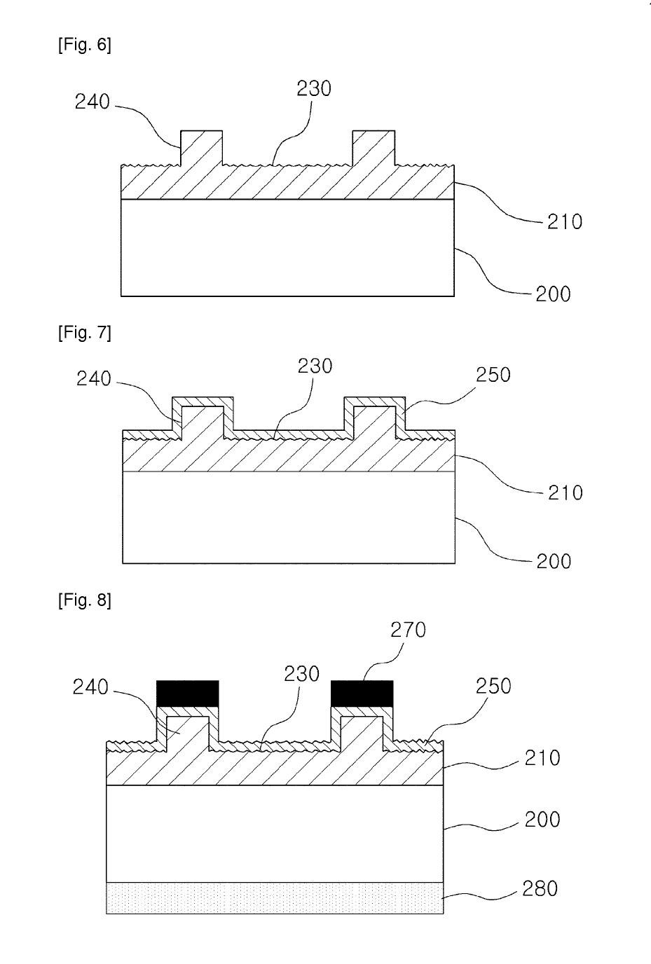

(e) The etching mask pattern 220 of FIG. 5 remaining after etch-back is removed at step S140 (see FIG. 6)

(f) A damage on a light receiving portion, i.e., a surface of the second emitter doping layer 230 of FIG. 6, is removed by performing a Damage Removal Etching (DRE) process on the silicon semiconductor substrate after removing the etching mask pattern on the silicon semiconductor substrate and an anti-reflective film is formed on a surface front of the silicon semiconductor substrate at steps S150 and S160 (see FIG. 7).

Accordingly, an anti-reflective film layer 250 of a predetermined thickness is deposited and laminated on the surface of the emitter doping layer 210 of the silicon semiconductor substrate 200. The anti-reflective film layer as a coating film for preventing reflection of light and improving efficient absorbance of light includes SiO, CeO2, Si3N4, and Al2O3.

(g) When the anti-reflective film layer 250 of FIG. 7 is formed, a front electrode and a rear electrode are formed by printing an electrode at step S170 (see FIG. 8). With reference to FIG. 8, a front electrode 270 is formed on an upper end of the first emitter doping layer 240 and a rear electrode 280 is formed on a lower end of the silicon semiconductor substrate 200.

The front electrode 270 has a state of maintaining a regular shape by applying a paste for the solar cell electrode before heat-treatment on the surface of the anti-reflective film layer 250 of the solar cell.

Powder paste such as copper, silver and aluminum may be used as the paste for the solar cell electrode. Generally, the front electrode 270 is formed by being printed on the anti-reflective film layer 250 as a grid pattern and being sintered. Also, the rear electrode 280 uses an aluminum metal.

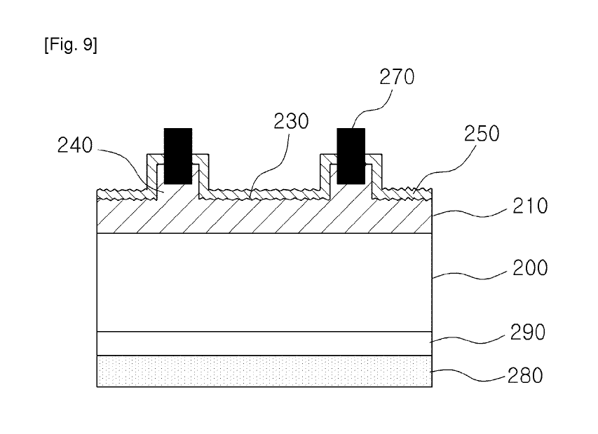

(h) According to further description with reference to FIG. 1, heat treatment is performed after printing an electrode at step S180. A solar cell is manufactured via the heat treatment process (see FIG. 9).

With reference to FIG. 9, since the paste for the solar cell electrode is not in a complete solid state, the paste for the solar cell electrode is solidified through a heat treatment, i.e., a firing process, and penetrates into the anti-reflective film layer 250 to be electrically connected.

The rear electrode 280 is formed on a lower end of the silicon semiconductor substrate 200. Accordingly, the silicon solar cell according to the present invention includes the silicon semiconductor substrate 200 doped with impurities of Group 3, the emitter doping layer 210 doped with impurities of Group 5 element on an upper portion of the silicon semiconductor substrate 200, the anti-reflective film layer 250 formed on a front of the silicon semiconductor substrate 200, the front electrode 270 accessing to the emitter doping layer 210 by penetrating the anti-reflective film layer 250 and a rear electrode 290 accessing to the rear of the silicon semiconductor substrate 200.

The emitter doping layer 210 is classified into the first emitter doping layer 240 dopes with impurities of the Group 5 element at a high concentration and the second emitter doping layer 230 dopes with impurities of the Group 5 element at a low concentration. The second emitter doping layer 230 has a feature that the emitter Rsh ranges from 70 Ohm/sq to 120 Ohm/sq.

A surface is textured to increase the sheet resistance and decrease the solar reflection rate at the same time. The emitter doping layer 210 is formed using an etching mask pattern as a mask on the emitter doping layer 210 accessing to the front electrode 270 by a screen print. The second emitter doping layer is formed by etch-back.

The first emitter doping layer 240 is a region accessing to the front electrode 270. An optical line width of the first emitter doping layer 240 ranges from 50 to 200 μm.

A p+ forming layer 290 is formed on an upper end of the rear electrode 280.

1. A solar cell, comprising:
a silicon semiconductor substrate;
an emitter doping layer having a surface, which is textured by a texturing process on an upper portion of the silicon semiconductor substrate and selectively doped;
an anti-reflective film layer formed on a front of the substrate;
a front electrode accessing to the emitter doping layer by penetrating the anti-reflective film layer; and
a rear electrode accessing to a rear of the silicon semiconductor substrate.

2. The solar cell of claim 1, wherein the silicon semiconductor substrate is doped with impurities of a Group 3 element or a Group 5 element, and the emitter doping layer is classified into a first emitter doping layer doped with impurities of the Group 3 element or the Group 5 element at a high concentration and a second emitter doping layer doped with the impurities of the Group 3 element or the Group 5 element at a low concentration,
wherein the first emitter doping layer is a region accessing to the front electrode.

3. The solar cell of claim 2, wherein the emitter doping layer is formed using an etching mask pattern as a mask on an emitter doping layer accessing to the front electrode by a screen print,
wherein a line width of the first emitter doping layer ranges from 50 to 200 μm and the second emitter doping layer is formed by etch-back.

4. The solar cell of claim 2, wherein in the emitter doping layers, the first emitter doping layer has a sheet resistance (Emitter Rsh) of 60 ohm/sq or less and the second emitter doping layer has an emitter Rsh ranging from 70 ohm/sq to 120 ohm/sq and is formed by etch-back.

5. A solar cell manufacturing method, comprising the steps of:
preparing a silicon wafer;
forming a silicon semiconductor substrate by Sawing Damage Removal (SDR) after sawing the silicon wafer;
forming an emitter doping layer on an upper portion of the silicon semiconductor substrate;
forming an etching mask pattern at a front electrode junction point on the emitter doping layer by a screen print;
performing Reactive Ion Etching (RIE) texturing on a surface of the emitter doping layer using the etching mask pattern as a mask and forming selective doping to form an emitter etch-back at the same time;
removing an etching mask pattern remaining after the etch-back;
removing damages on the surface of the emitter doping layer using Damage Removal Etching (DRE) on the silicon semiconductor substrate;
forming an anti-reflective film on a front of the silicon semiconductor substrate;
forming a front electrode by penetrating the anti-reflective film; and
forming a rear electrode on a rear of the silicon semiconductor substrate.

6. The solar cell manufacturing method of claim 5, wherein the silicon semiconductor substrate is doped with impurities of a Group 3 element or a Group 5 element, and the emitter doping layer is classified into a first emitter doping layer doped with impurities of the Group 3 element or the Group 5 element at a high concentration and a second emitter doping layer doped with the impurities of the Group 3 element or the Group 5 element at a low concentration,
wherein the first emitter doping layer is a region accessing to the front electrode.

7. The solar cell manufacturing method of claim 5,
wherein in the step of forming the etching mask pattern, the etching mask pattern is formed by screen-printing a paste.

8. The solar cell manufacturing method of claim 5, wherein in the step of forming the selective doping, etch-back on the emitter doping layer is performed using dry etchant, in which etch gas and O₂ are mixed, and surface texturing is performed at the same time.

9. The solar cell manufacturing method of claim 6, wherein in the emitter doping layers, the first emitter doping layer has a sheet resistance (Emitter Rsh) of 60 ohm/sq or less and the second emitter doping layer has an emitter Rsh ranging from 70 ohm/sq to 120 ohm/sq.

10. The solar cell manufacturing method of claim 5, wherein the emitter doping layer after etch-back via the step of forming the selective doping has the greater emitter Rsh than the emitter doping layer before etch-back.

11. The solar cell manufacturing method of claim 6, wherein a line width of the first emitter doping layer ranges from 50 to 200 μm.

12. The solar cell manufacturing method of claim 6, wherein in the step of forming the etching mask pattern, the etching mask pattern is formed by screen-printing a paste.

13. The solar cell manufacturing method of claim 6, wherein in the step of forming the selective doping, etch-back on the emitter doping layer is performed using dry etchant, in which etch gas and O₂ are mixed, and surface texturing is performed at the same time.

14. The solar cell manufacturing method of claim 6, wherein the emitter doping layer after etch-back via the step of forming the selective doping has the greater emitter Rsh than the emitter doping layer before etch-back.
